(19) United States
(12) Patent Application Publication
(10) Pub. No.: US 2005/0279630 A1
(43) Pub. Date: Dec. 22, 2005

(54) Tubular sputtering targets and methods of flowforming the same

(75) Inventor: Matthew V. Fonte, Charlestown, MA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: Dynamic Machine Works, Inc., Billerica, MA (US)

(21) Appl. No.: 11/111,495

(22) Filed: Apr. 21, 2005

Related U.S. Application Data
(63) Continuation-in-part of application No. 11/004,622, filed on Dec. 3, 2004.
(60) Provisional application No. 60/580,472, filed on Jun. 16, 2004.
(60) Provisional application No. 60/605,489, filed on Aug. 30, 2004.

(51) Int. Cl. C23C 14/34

(52) U.S. Cl. 204/298.21; 204/298.22; 164/47

(57) ABSTRACT

Described herein are sputtering target tubes and methods of making sputtering target tubes. The methods include a step of forming a metal hollow preform and flowforming the metal hollow preform to form a sputtering target tube. The step of forming a metal hollow preform can include such processes as extrusion, hot isostatic pressing of a metal powder, rotary-piercing, casting, machining a billet, and plasma spray-forming. In some embodiments, the tubular sputter targets have a variable wall-thickness.

### RELATED APPLICATIONS

This application is a continuation-in-part of U.S. application Ser. No. 11/004,622, filed Dec. 3, 2004, which claims the benefit of U.S. Provisional Application No. 60/580,472 filed on Jun. 16, 2004, and 60/605,489 filed on Aug. 30, 2004. The entire teachings of the above applications are incorporated herein by reference.

### BACKGROUND OF THE INVENTION

Cathode sputtering processes are widely used for depositing thin coatings or films of material onto substrates. Such a process takes place in an evacuated chamber containing a small quantity of an ionizable gas (e.g., argon). Electrons emitted from a source held within the chamber ionize the gas to form a plasma and the ions produced bombard a target comprising the material to be sputtered, thereby causing atoms of the target material to be dislodged and subsequently deposited as a film on the substrate being coated.

In a magnetron apparatus the rate of deposition may be increased by the use of magnetic means (e.g., an array of magnets positioned in a predetermined manner, such as a closed loop) to define an area or region, often referred to as the “race-track,” from which sputtering or erosion of the target occurs. The substrate being coated is moved continuously or intermittently relative to the target during the sputtering process.

Sputtering targets come in a variety of forms, including flat, elongated rectangles or hollow cylinders or tubes. The rectangular targets are generally used in planar magnetrons, while the tubular targets are usually used in rotatable or cylindrical magnetrons. The race track produced by planar magnetrons tends to be small, causing only a small portion of the total target surface area to be consumed before the rectangular targets need to be replaced. However, in cylindrical magnetrons, the tubular target can be rotated about its longitudinal axis, either continuously or intermittently, so that sputtering is not confined to one particular area of the target surface. The ability to rotate the targets, and thereby use more of the target material, is advantageous because the targets are often formed from expensive metals.

Current methods of forming sputtering target tubes are generally inefficient, with large portions of the valuable metal being machined away to form the tube. One method of forming a target tube involves extruding a cylinder followed by machining to refine the dimensions of the sputtering target. The metal that is machined from the cylinder can occasionally be recycled, however, machining and recycling necessitate additional steps that add to the costs and complexity of the target production process.

A need exists in the art for more efficient methods of forming or producing sputtering target tubes.

### SUMMARY OF THE INVENTION

This invention provides hollow tubular sputtering targets and methods of making or forming the same.

In some embodiments, this invention features a method of making a sputtering target tube comprising the steps of producing a metal hollow preform and flowforming the metal hollow preform to form a sputtering target tube. The metal hollow preform has two open ends, and the step of producing the metal hollow preform can include extrusion, hot isostatic pressing, rotary-piercing, casting, machining of a billet or bar, and/or plasma spray-forming. Optionally, the methods include additional steps of annealing and/or machining the metal hollow preform. The methods can also optionally include additional steps of annealing and/or machining the flowformed sputtering target tube or a partially flowformed sputtering target tube.

In other embodiments, this invention features a method of making a sputtering target tube comprising the steps of producing a metal hollow preform, and flowforming the metal hollow preform to form a sputtering target tube that has a dog bone shape. The metal hollow preform has two open ends.

In some embodiments, this invention features a sputtering target comprising a hollow cylinder having two open ends and a major axis. At least a portion of the hollow cylinder is made of a metal having a hexagonal close packed crystal structure with a crystal texture that has basal planes orientated radially with respect to the major axis of the cylinder.

The methods of this invention simplify the production of sputtering target tubes. These methods reduce or eliminate the production of waste metal and/or the need to recycle such waste metals, thereby resulting in more efficient sputtering target production, which results in reduced production costs and/or ultimately cheaper sputtering target tubes. The methods of this invention can produce, and the targets of this invention can have, increased biaxial strength. Also, the targets of this invention have a finer, more uniform radial grain structure than sputtering targets produced by prior art methods, which results in a more uniform and/or consistent sputtering action.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 illustrates a schematic diagram showing a side-view of exemplary forward flowforming device.

FIG. 2 illustrates a schematic diagram showing a side-view of exemplary reverse flowforming device.

FIG. 3 graphically illustrates orientations used to describe crystallographic and grain structures of metallic sputtering target tubes.

FIG. 4 illustrates the crystallographic orientation of an hcp-metal target formed with a prior art extrusion process.

FIG. 5 is a schematic diagram illustrating the crystallographic texture of a portion of an hcp-metal target formed by a prior art extrusion process.

FIG. 6 illustrates the crystallographic orientation of an hcp-metal target of the present invention.

FIG. 7 is a schematic diagram illustrating the crystallographic texture of a portion of an hcp-metal target of the present invention.

FIG. 8 illustrates a 500× magnification of an etched microstructure of material taken from a sample of a titanium CP2 hollow formed via an extrusion process.

FIG. 9 illustrates a 500× magnification of an etched microstructure of material taken from a sample of a sputtering target tube formed by flowforming a titanium CP2 hollow preform.

### DETAILED DESCRIPTION OF THE INVENTION

A description of preferred embodiments of the invention follows. While this invention has been particularly shown and described with references to preferred embodiments thereof, it will be understood by those skilled in the art that various changes in form and details may be made therein without departing from the scope of the invention encompassed by the appended claims.

In some embodiments, this invention features methods of making a sputtering target in the shape of a tube. The methods comprise the steps of producing a metal hollow preform (i.e., a hollow metal shape that is suitable for flow-flowforming) and flowforming the metal hollow preform to form a sputtering target tube.

Flowforming is an advanced cold-forming process for the manufacture of hollow components. Flowforming allows for the production of dimensionally precise and rotationally symmetrical components and is typically performed by compressing the outside diameter of a cylindrical component or preform using a combination of axial and radial forces from one or more rollers. The metal is compressed and plasticized above its yield strength and made to flow in the axial direction onto a mandrel. The workpiece being formed, the rollers, and/or the mandrel can rotate. Two examples of flowforming methods are forward flowforming and reverse flowforming. Generally, forward flowforming is useful for forming tubes or components having at least one closed or semi-closed end (e.g., a closed cylinder). Reverse flowforming is generally useful for forming tubes or components that have two open ends (e.g., a tube having two open ends).

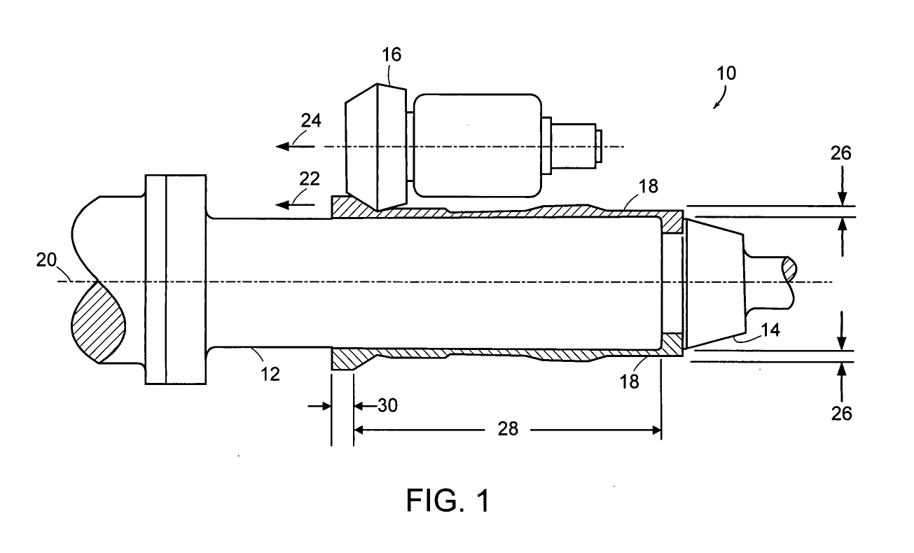

FIG. 1 illustrates a schematic diagram showing a side-view of exemplary forward flowforming device 10. Device 10 includes mandrel 12, tailstock 14, and roller 16. Preform 18 is a metal or metal alloy tube or hollow cylinder having one open end.

In operation, preform 18 is placed over mandrel 12. Mandrel 12 rotates about major axis 20. Tailstock 14 applies an amount of force or pressure to preform 18 to cause the preform to rotate with mandrel 18. As mandrel 12 and preform 18 rotate, roller 16 is moved into a position so that it contacts the outer surface of preform 18 at a desired point along the length of the preform. Roller 16 compresses the outer surface of preform 18 with enough force so that the metal of the preform is plasticized and caused to flow in direction 22, generally parallel to axis 20. Roller 16 can be positioned at any desired distance from the outer diameter of mandrel 12 or the inner wall of preform 18, thereby compressing the walls of the preform to any desired thickness at the point of compression. For example, the walls of preform 18 can be compressed to width 26 at a point of compression.

While mandrel 12 and preform 18 continue to rotate, roller 16 is moved down the length of preform 18, generally in direction 24, thereby compressing additional portions of the length of preform 18 to a desired thickness. As it moves down the length of preform 18, roller 16 can be positioned at different distances relative to mandrel 12 or it can be kept at the same distance relative to mandrel 12. As the roller(s) move(s) down the length of a preform, the roller(s) deform(s) the preform into a metal or metal alloy tube having walls with a desired thickness or thicknesses. In FIG. 1, length 28 represents the portion of the preform that has been formed into the metal tube. Length 30 represents additional portions of the preform that have yet to be formed. This operation is termed “forward flowforming” because the deformed material flows in the same direction that the rollers are moving.

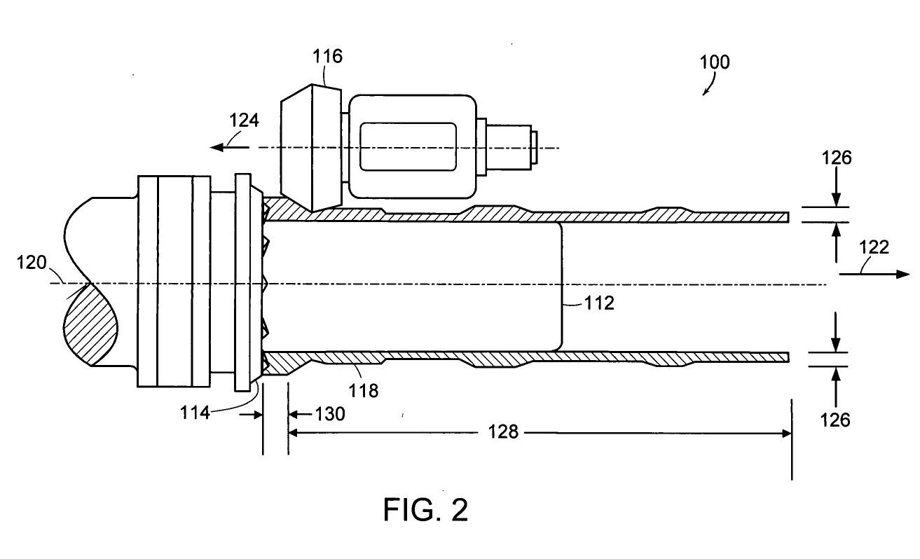

FIG. 2 illustrates a schematic diagram showing a side-view of exemplary reverse flowforming device 100. Device 100 includes mandrel 112, drive ring 114, and roller 116. Preform 118 is a metal or metal alloy tube or hollow cylinder having two open ends.

In operation, preform 118 is placed over mandrel 112 and pushed against drive ring 114. Mandrel 112 rotates about major axis 120. As mandrel 112 rotates, roller 116 is moved into a position so that it contacts the outer surface of preform 118 at a desired point along the length of the preform. Roller 116 presses preform 118 against drive ring 114, thereby causing preform 118 to rotate with mandrel 112. Drive ring 114 has a series of protruding splines on its face or other means for securing preform 118 so that it will rotate with mandrel 112. Roller 116 compresses the outer surface of preform 118 with enough force so that the metal of the preform is plasticized and caused to flow under roller 116 and in direction 122, generally parallel to axis 120. Roller 116 can be positioned at any desired distance from the outer diameter of mandrel 112 or the inner wall of preform 118, thereby compressing the walls of the preform to any desired thickness at the point of compression. For example, the walls of preform 118 can be compressed to width 126 at a point of compression.

While mandrel 112 and preform 118 continue to rotate, roller 116 is moved down the length of preform 118, generally in direction 124, thereby compressing additional portions of the length of preform 118 to a desired thickness or thicknesses. As the roller(s) move(s) down the length of a preform, the roller(s) deform(s) the preform into a metal or metal alloy tube having walls with any desired thickness. In FIG. 2, length 128 represents the portion of the preform that has been formed into the metal tube. Length 130 represents additional portions of the preform that have yet to be formed. As the tube is formed, it is extended down the length of the mandrel away from drive ring 114. This operation is termed “reverse flowforming” because the deformed material flows in the direction opposite to the direction that the rollers are moving.

Metal Hollow Preform

The metal hollow preform of the present invention comprises a metal or metal alloy which is to be sputtered onto a substrate. For example, the metal hollow preform can include aluminum, cobalt, chromium, copper, indium, iron, magnesium, manganese, molybdenum, nickel, niobium, palladium, platinum, silver, stainless steel, tantalum, tin, titanium, tungsten, vanadium, zinc, zirconium, or mixtures or alloys thereof, such as, for example, a nickel-chrome alloy (e.g., 80/20 weight % nickel/chromium alloy). Preferably, the metal hollow preform includes a metal that is commonly sputtered onto glass and/or has an hcp-crystal structure (i.e., a hexagonal closed packed crystal structure). Examples of metals having an hcp-crystal structure are well know in the art.

The metal hollow preform is in a shape which can be subjected to flowforming. For example, the metal hollow preform can be in the shape of a closed-bottom cylinder or a tube (e.g., a hollow tube or cylinder having one or two open ends).

The step of producing the metal hollow preform can include a variety of processes. Examples of processes useful for producing the metal hollow preform include extrusion, hot isostatic pressing (also referred to as “HIPing”), rotary-piercing, casting, machining, plasma spray-forming, and combinations thereof.

In some embodiments, the step of producing a metal hollow preform includes extruding at least a portion of a metal. In further embodiments, the step of producing the metal hollow preform includes extruding a portion of metal selected from the group consisting of a bar, a billet, a consolidated metal powder (e.g., a metal powder that has been HIPed), and/or a metal casting. In additional embodiments, the step of producing the metal hollow preform includes casting a metal preform. In yet further embodiments, the step of producing the metal hollow preform includes plasma spray-forming a metal preform. In still more embodiments, the step of producing the metal hollow preform includes machining a cast billet, a cast bar, a cast hollow, a rolled bar, or a rolled billet.

Sputtering Target Tube

The metal hollow preform is flowformed to form a sputtering target tube or hollow cylinder. The sputtering target tube of the present invention comprises a metal or metal alloy that is suitable for sputtering onto a substrate. For example, the metal hollow preform can include aluminum, cobalt, chromium, copper, indium, iron, magnesium, manganese, molybdenum, nickel, niobium, palladium, platinum, silver, stainless steel, tantalum, tin, titanium, tungsten, vanadium, zinc, zirconium, or mixtures or alloys thereof, such as, for example, a nickel-chrome alloy (e.g., 80/20 weight % nickel/chromium alloy). Preferably, the sputtering target tube includes a metal that is commonly sputtered onto glass and/or has an hcp-crystal structure.

The sputtering target tube that is formed can be in any desired shape that is suitable for use as a sputtering target tube. For example, the sputtering target tube can be in the shape of a closed-bottom cylinder or tube (e.g., a hollow tube or cylinder having one or two open ends).

The sputtering target tube can be any desired length. For example, the sputtering target tube can be about 30 feet (˜9.14 meters) or more in length, about 30 feet (˜9.14 meters) or less in length, about 20 feet (˜6.1 meters) or less in length, about 10 feet (˜3.05 meters) or less in length, about 24 inches (˜0.61 meters) or less in length, about 12 inches (˜0.305 meters) or less in length, or about 6 inches (˜0.152 meters) or less in length.

The formed sputtering target tube can have any desired wall thickness (i.e., the distance between the inner and outer surfaces of the tube or the distance between the inner and outer diameters of the tube at a point along the length of the sputtering target tube). For example, the sputtering target can have a wall thickness of about 0.75 inches (˜19.05 millimeters) or less, between about 0.5 inches (˜12.7 millimeters) and about 0.025 inches (˜0.635 millimeters), or less than about 0.025 inches (˜0.635 meters). In some preferred embodiments, the wall thickness varies along some portion of the length of the sputtering target tube. For example, the formed sputtering target tube can have a wall thickness at one or more positions along the length of the target that is unequal to the wall thickness at the remaining positions along the length of the formed sputtering target tube. In another example, the wall thickness at one or both ends of the tube is thicker than at other points along the length of the formed sputtering target tube. In yet another example, the wall thickness of the formed sputtering target tube increases or decreases along the length or one or more portions of the length of the tube. In especially preferred embodiments, the formed sputtering target tube has a “dog bone” shape (i.e., the wall thickness at both ends of the tube is greater, though not necessarily in uniform steps, than the wall thickness at some middle portion of the length of the tube).

The formed sputtering target tube can have any desired outer and inner diameter.

For example, the formed sputtering target tube can have an outer diameter of about 15 inches (˜381 millimeters) or less, about 12 inches (˜305 millimeters) or less, about 10 inches (˜254 millimeters) or less, about 6 inches (˜152 millimeters) or less and/or an inner diameter of about 1 inch (˜25.4 millimeters) or greater, about 2 inches (˜50.8 millimeters) or less, about 4 inches (˜102 millimeters) or less, about 4.9 inches (˜124 millimeters) or less, about 5 inches (˜127 millimeters) or less, about 10 inches (˜254 millimeters) or less, about 12 inches (˜304.8 millimeters) or less, and about 15 inches (˜381 millimeters) or less.

In some embodiments of the invention, the step of flowforming the metal hollow preform to form a sputtering target tube includes one or more forward flowforming components. In other embodiments of the invention, the step of flowforming the metal hollow preform includes one or more reverse flowforming components. In further embodiments of the invention, the step of flowforming the metal hollow preform includes one or more reverse flowforming components and one or more forward flowforming components.

Annealing

In some embodiments of the invention, one or more optional annealing steps are performed. For example, the metal hollow preform can be annealed before the flowforming step and/or the sputtering target tube can be annealed after it is flowformed.

Optionally, one or more annealing steps can be performed between flowforming steps. For example, a metal hollow preform can be subjected to one or more flowforming steps to create a partially flowformed sputtering target tube and the partially flowformed sputtering target tube is then annealed. The annealed partially flowformed sputtering target tube can then be flowformed into a sputtering target tube. In some embodiments, the entire flowforming process is interspersed with a plurality of annealing steps or passes.

Machining

In some embodiments of the invention, one or more optional machining steps are performed. For example, the metal hollow preform can be machined before the flowforming step. Such optional machining steps are useful for ensuring the metal hollow preform will have dimensions sufficient to properly fit onto a mandrel of a flowforming machine (e.g., a predetermined inner and/or outer diameter over some portion of the length of the preform). A preform that does not properly fit onto the mandrel may result in an improper sputtering target tube and/or damage to the flowforming tooling and/or machine. Preferably, the preform is machined in order to produce a preform with a concentric inner and outer diameter that results in a concentrically even sputtering target tube. Machining the preform can also be useful for ensuring the sputtering target tube has desirable dimensions or a desirable volume.

In another embodiment, the formed sputtering target tube is optionally machined. Further, the preform that is being flowformed can be machined between flowforming steps or passes.

This invention also encompasses sputtering targets that comprise a metal having an hcp-crystal structure and possess unique metallurgical structures and/or unique crystallographic structures. Examples of metals having an hcp-crystal structure are well known in the art and include metals such as beryllium, cobalt, neodymium, ruthenium, zinc, zirconium, and alloys thereof.

The unique metallurgical structures and/or unique crystallographic structures possessed by the targets of this invention can be produced or imparted by forming the targets with methods of this invention. Due to the unique metallurgical structures and/or crystallographic structures, the sputtering targets of this invention often have unique and advantageous metallurgical properties (e.g., superior biaxial strength, superior hoop strength, and/or finer and more consistent grain structures compared to targets formed by prior art methods).

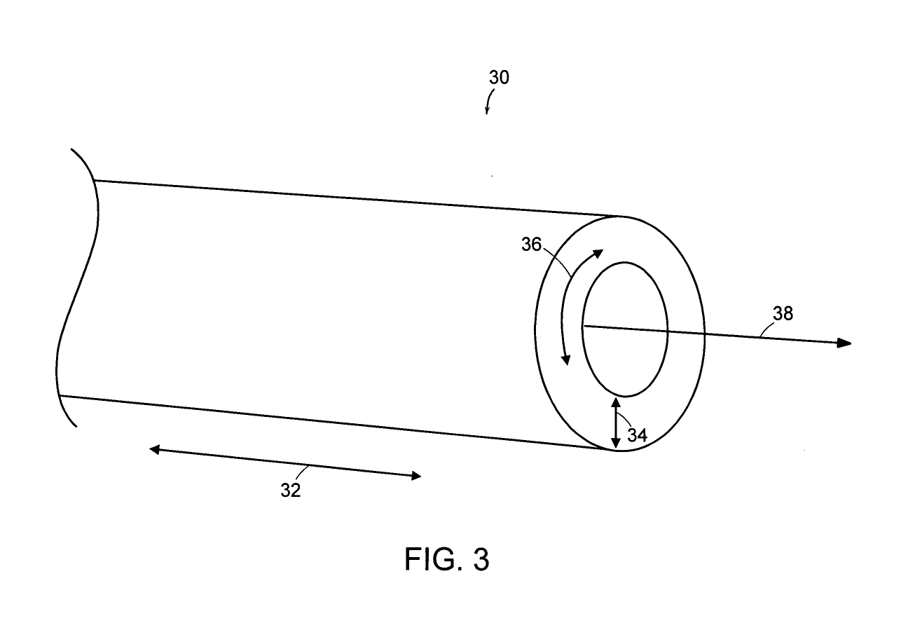

Generally, the crystallographic and grain structures of metallic sputtering target tubes are described using three orientations, including a longitudinal orientation, a radial orientation, and a circumferential orientation. FIG. 3 graphically illustrates examples of such orientations, including longitudinal orientation 32, radial orientation 34, and circumferential orientation 36, all useful for describing crystallographic texture and grain structures of a metallic sputtering target tube 30 having major axis 38. Longitudinal orientation 32 runs along a surface of the tube or in the tube and is parallel to major axis 38. Radial orientation 34 lies along a line that emanates from the center of the tube and is normal to major axis 38 and longitudinal orientations (e.g., longitudinal orientation 32). Circumferential orientation 36 runs along a surface of the tube or in the tube, and lies in a circumference of the tube wall (i.e., along a curved line that both lies in a plane normal to major axis 38 and is normal to radial orientations such as, for example, radial orientation 34).

In some embodiments, the target of this invention have a unique grain orientation. For example, a target formed using a prior art extrusion process will typically exhibit grains that are equiaxed. That is, the grains of a target formed using a prior art extrusion process will typically be uniform in shape in all three orientations. A target formed in accordance with the methods of this invention, however, generally exhibits grains that are shaped like an “elongated pancake,” with the length of the grains relatively flattened in the radial orientation and relatively elongated in both the circumferential and longitudinal orientations, with the elongation being more pronounced in the longitudinal orientation than the circumferential orientation. That is, the targets of this invention have grains that are:
1. Elongated substantially in the longitudinal orientation;
2. Elongated in the circumferential orientation, although not to the same degree as the elongation in the longitudinal orientation; and
3. Flattened or shortened in the radial orientation.

In some embodiments, the targets of this invention have an average grain size that is smaller or finer than that found in targets made by prior art methods. For example, the equiaxed grains of a target formed using a prior art extrusion process will typically be sized at about No. 8 on the ASTM E112 scale or larger size. The grains of the targets of the present invention, however, generally exhibit a grain size of No. 11, 12, or finer (on the ASTM E112 scale) along the radial orientation. (Higher numbers on the ASTM E112 scale signify finer grain structure.) Hence, the targets of this invention have a finer grain size. In some embodiments, the targets of this invention have an average grain length in the radial orientation that is no greater than about 0.00025 inches, preferably no greater than about 0.0001 inches.

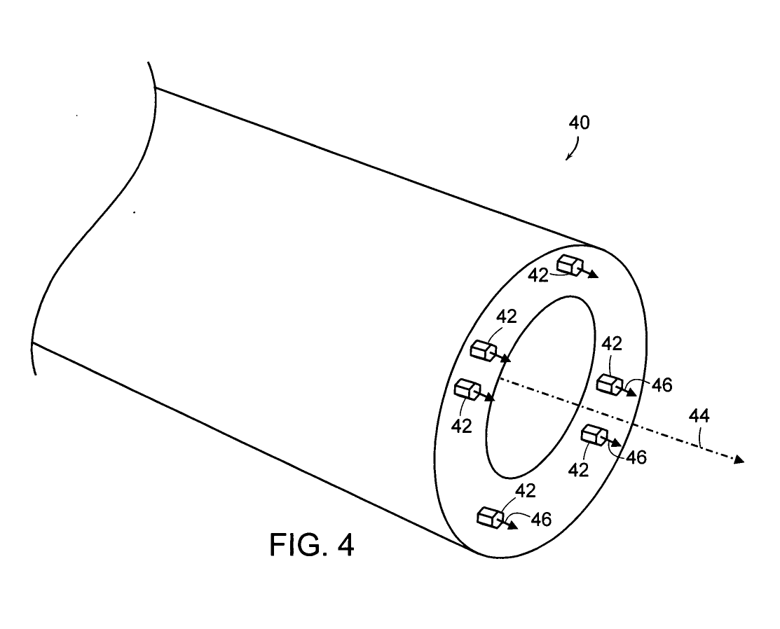

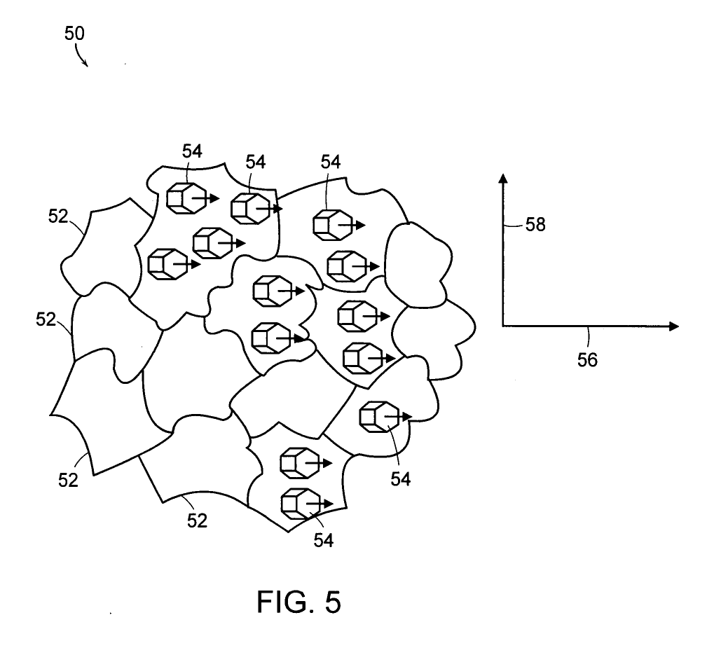

In some embodiments, targets of this invention have a unique crystallographic texture compared to that of targets formed with prior art methods. For example, targets made of a metal having an hcp (hexagonal closed-pack) crystal structure and formed with a prior art extrusion method exhibit a crystallographic texture having basal planes orientated or stacked in a longitudinal direction. That is, hcp-metal targets formed by a prior art extrusion process exhibit a crystallographic texture where:
1. The c-axes of the hexagonal cells are collinear to lines running in longitudinal orientations, normal to lines running in radial orientations, and normal to lines running in circumferential orientations; and
2. The basal planes are normal to lines running in longitudinal orientations, coplanar with lines running in radial orientations, and coplanar with lines running in circumferential orientations.
   FIG. 4 illustrates the crystallographic orientation of an hcp-metal target formed with a prior art extrusion process. Target 40 includes hexagonal cells 42 and major axis 44. The c-axes 46 of cells 42 run parallel to major axis 44. The basal planes of cells 42 are coplanar with planes that are normal to major axis 44. FIG. 5 is another schematic diagram illustrating the crystallographic texture of a portion of an hcp-metal target formed by a prior art extrusion process. Portion 50 includes a plurality of equiaxed grains 52. Grains 54 include hexagonal crystal cells 54. The c-axes of cells 54 are collinear or parallel with lines running in longitudinal orientation 56. The basal planes of cells 54 are coplanar or lie in planes parallel to radial orientation 58. (The relative size of the hexagonal cells in FIGS. 4 and 5 have been exaggerated for clarity.)

Targets of the present invention that are made of a metal having an hcp crystal structure, however, exhibit a crystallographic texture having basal planes orientated or stacked in a radial direction. That is, hcp-metal targets formed by the methods of this invention exhibit a crystallographic texture where:
1. The c-axes of the hexagonal cells are normal to lines running in longitudinal orientations, collinear to lines running in radial orientations, and normal to lines running in circumferential orientations; and
2. The basal planes are coplanar with lines running in longitudinal orientations, normal to lines running in radial orientations, and coplanar with lines running in circumferential orientations.

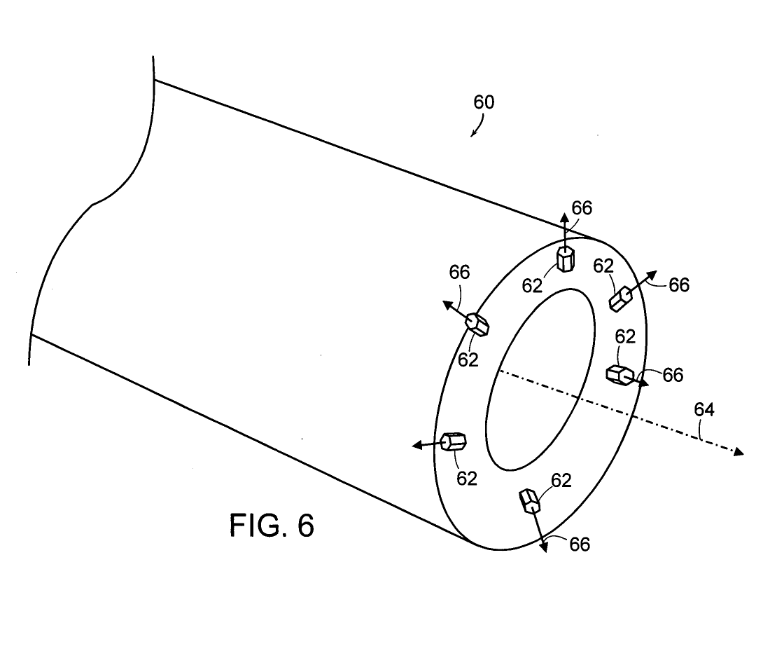

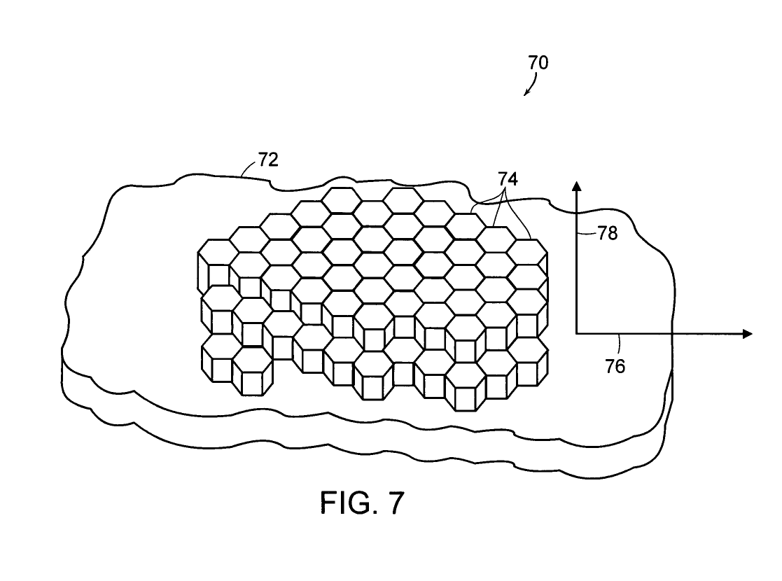

FIG. 6 illustrates the crystallographic orientation of an hcp-metal target of the present invention. Target 60 includes hexagonal cells 62 and major axis 64. The c-axes 66 of cells 62 are normal to lines that run parallel to major axis 64. The basal planes of cells 62 are coplanar with planes that are parallel to major axis 64. FIG. 7 is another schematic diagram illustrating the crystallographic texture of a portion of an hcp-metal target formed of the present invention. Portion 70 includes an “elongated pancake” shaped grain 72. Grain 72 includes hexagonal crystal cells 74. The c-axes of cells, 74 are normal to lines running in longitudinal orientation 76. The basal planes of cells 74 are normal to lines that are collinear or parallel to radial orientation 78. (The relative size of the hexagonal cells in FIGS. 6 and 7 have been exaggerated for clarity.)

Some metals are soft enough that the heat encountered during a sputtering process can cause targets made from them to sag or bend during the sputtering processes. Such targets often have to be braced or supported with backing tubes (e.g., stainless steel backing tubes) so they do not deform to an unacceptable degree. For example, sputtering tubes made of tin, silver, or aluminum often must be placed on a mandrel during the sputtering process, lest the increased heat cause the tube to warp and bend. The increased biaxial strength of the targets of this invention minimizes or eliminates the need for such braces or supports.

It is also believed that the finer, more uniform, grain structure of the sputtering targets of this invention provide for a more uniform and/or consistent sputtering action than that obtained from prior art sputtering targets.

In one embodiment, this invention features a sputtering target, comprising a hollow cylinder having two open ends and a major axis, wherein at least a portion of the hollow cylinder is made of a metal having an hcp crystal structure having hexagonal crystal cells, the hexagonal cells having basal planes aligned in a radial direction.

Some prior art processes used to produce sputtering targets resulted in targets having voids or pores in the sputtering metal forming the target. For example, silver can be problematic to shape and form in a desired sputtering target shape. Prior art methods often use spray-forming processes to produce a desired shaped silver target. Basically, multiple layers of silver metal are sprayed onto a desired shape, thereby resulting in a target made from a plurality of layers of silver metal. However, these multiple layers often trap air or contaminants, resulting in a target having a plurality of voids or pores within the sputtering metal that produce undesirable sputtering performance.

This invention includes sputtering target tubes, and methods of making sputtering target tubes, that are “100% dense.” As used herein, “100% dense” means a target that is substantially free of voids or pores.

The following example is illustrative of the invention and is not meant to be limiting in any way.

### EXAMPLE

### Metallurgical Comparison

A metallurgical evaluation of two samples of commercially pure titanium grade 2 (“CP2”) tubing material was conducted. The first sample was taken from a metal hollow preform that was formed via an extrusion process. The second sample was taken from a sputtering target tube formed by flowforming a metal hollow preform that had been formed via an extrusion process.

The grain structure of the two samples was determined through preparation of metallographic cross sections in the three orientations described above, namely a longitudinal orientation, a radial orientation, and a circumferential orientation.

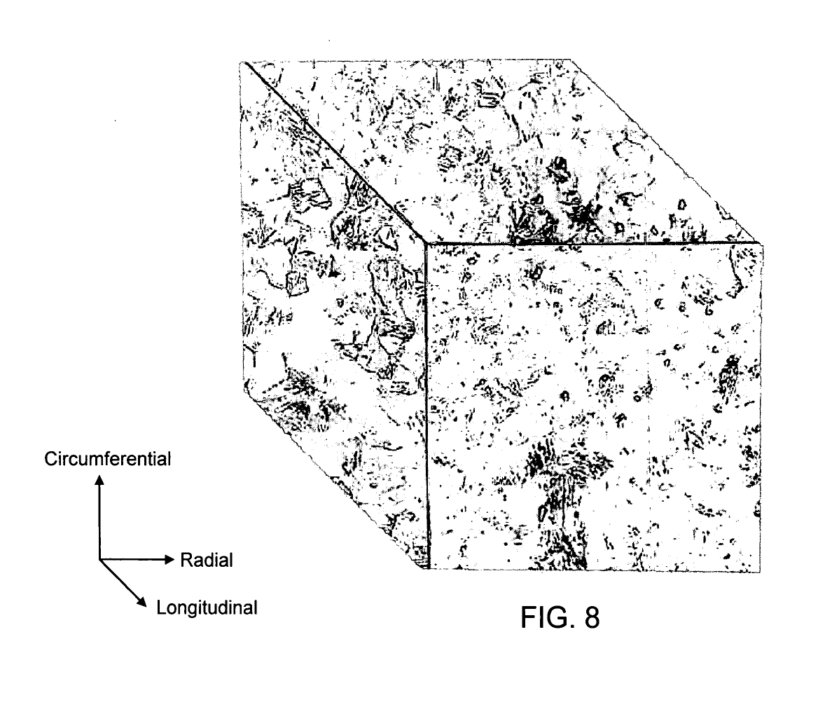

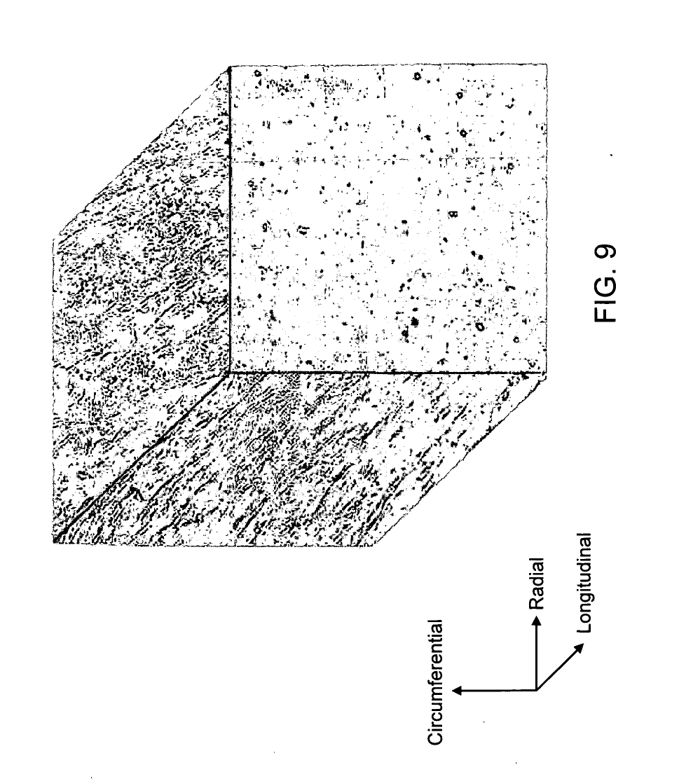

The metallurgical microstructure was documented by photographing the etched cross sections at 500× magnification. The microphotographs in each orientation were combined to create a simulated three-dimensional view of the grain structure in the three orientations. The 500× magnification of the microstructure of material of the first sample (i.e., the sample taken from the preform formed via an extrusion process) is shown in FIG. 8. The 500× magnification of the microstructure of the material of the second sample (i.e., the sample taken from the sputtering target tube formed by flowforming a metal hollow preform that had been formed via an extrusion process) is shown in FIG. 9.

As shown in FIGS. 8 and 9, the microstructure of the material from the second sample was significantly altered compared to the microstructure of the material from the first sample. The microstructure of the first sample composed of extruded material was equiaxed, meaning the grains were of a uniform shape in all three directions. The average grain size of the first sample were significantly larger than that of the second sample, measuring approximately 0.0005 inches (˜0.0127 millimeters). The grains of the second sample had been elongated and flattened to create a general “elongated pancake” shape. The grain size in the radial orientation were very fine, having an average grain diameter of approximately 0.0001 inches (˜0.00254 millimeters).

The crystallographic texture of the two samples were determined using x-ray diffraction techniques. The results of the crystallographic texture analysis of the two samples revealed very significant differences between the two samples. The overall crystallographic texture of the first sample includes longitudinally oriented basal planes, which is typical for extruded metals having a hexagonal close packed crystal structure. That is, the c-axes of the hexagonal cells were collinear to lines running in longitudinal orientations, normal to lines running in radial orientations, and normal to lines running in circumferential orientations, while the basal planes were normal to lines running in longitudinal orientations, coplanar with lines running in radial orientations, and coplanar with lines running in circumferential orientations.

The overall texture of the second sample was radially oriented basal planes of the hexagonal close-packed crystal structure of the material. That is, the c-axes of the hexagonal cells were normal to lines running in longitudinal orientations, collinear to lines running in radial orientations, and normal to lines running in circumferential orientations, while the basal planes were coplanar with lines running in longitudinal orientations, normal to lines running in radial orientations, and coplanar with lines running in circumferential orientations.

1. A method of making a sputtering target tube, the method comprising the steps of:
a) producing a metal hollow preform; and
b) flowforming the metal hollow preform to form a sputtering target tube, wherein the sputtering target tube has two open ends.

2. The method of claim 1, wherein the step of producing the metal hollow preform includes extruding at least a portion of the metal.

3. The method of claim 2, wherein the portion of the metal that is extruded is in at least one of the forms selected from the group consisting of a bar, a billet, a consolidated metal powder, and a metal casting.

4. The method of claim 1, wherein the step of producing the metal hollow preform includes hot isostatic pressing at least a portion of metal powder.

5. The method of claim 1, wherein the step of producing the metal hollow preform includes rotary-piercing a metal preform.

6. The method of claim 1, wherein the step of producing the metal hollow preform includes casting a metal preform.

7. The method of claim 1, wherein the step of producing the metal hollow preform includes machining a cast billet, a cast bar, a cast hollow, a rolled bar, or a rolled billet.

8. The method of claim 1, wherein the step of producing the metal hollow preform includes plasma spray-forming a metal preform.

9. The method of claim 1, further including a step of annealing the metal hollow preform before the flowforming step.

10. The method of claim 1, further including a step of machining the metal hollow preform before the flowforming step.

11. The method of claim 1, wherein the flowforming step is interspersed with at least one annealing step.

12. The method of claim 1, further including a step of annealing the sputtering target tube.

13. The method of claim 1, wherein the flowforming step has a reverse flowforming component.

14. The method of claim 1, wherein the flowforming step has a forward flowforming component.

15. The method of claim 1, wherein the formed sputtering target tube is 30 feet long or less.

16. The method of claim 1, wherein the formed sputtering target tube has an inner diameter of 15 inches or less.

17. The method of claim 1, wherein the formed sputtering target tube has an outer diameter of 15 inches or less.

18. The method of claim 1, wherein the formed sputtering target tube has a wall thickness of at least 0.010 inches.

19. The method of claim 1, wherein the formed sputtering target tube has a dog bone shape.

20. The method of claim 1, wherein the formed sputtering target tube has a wall thickness at one or more positions along the length of the target that is unequal to the wall thickness at the remaining positions along the length of the formed sputtering target tube.

21. The method of claim 1, wherein the formed sputtering target tube includes at least one metal selected from the group consisting of aluminum, cobalt, chromium, copper, indium, iron, magnesium, manganese, molybdenum, nickel, niobium, palladium, platinum, silver, stainless steel, tantalum, tin, titanium, tungsten, vanadium, zinc, zirconium, or alloys thereof.

22. The method of claim 1, wherein the metal hollow preform has at least one open end.

23. The method of claim 22, wherein the metal hollow preform has two open ends.

24. A method of making a sputtering target tube, the method comprising the steps of:
a) producing a metal hollow preform, wherein the metal hollow preform has two open ends; and
b) flowforming the metal hollow preform to form a sputtering target tube.

25. The method of claim 24, wherein the step of producing the metal hollow preform includes extruding at least a portion of the metal.

26. The method of claim 25, wherein the portion of the metal that is extruded is in at least one of the forms selected from the group consisting of a bar, a billet, a consolidated metal powder, and a metal casting.

27. The method of claim 24, wherein the step of producing the metal hollow preform includes hot isostatic pressing at least a portion of metal powder.

28. The method of claim 24, wherein the step of producing the metal hollow preform includes rotary-piercing a metal preform.

29. The method of claim 24, wherein the step of producing the metal hollow preform includes casting a metal preform.

30. The method of claim 24, wherein the step of producing the metal hollow preform includes machining a cast billet, a cast bar, a cast hollow, a rolled bar, or a rolled billet.

31. The method of claim 24, wherein the step of producing the metal hollow preform includes plasma spray-forming a metal preform.

32. The method of claim 24, further including a step of annealing the metal hollow preform before the flowforming step.

33. The method of claim 24, further including a step of machining the metal hollow preform before the flowforming step.

34. The method of claim 24, wherein the flowforming step is interspersed with at least one annealing step.

35. The method of claim 24, further including a step of annealing the sputtering target tube.

36. The method of claim 24, wherein the flowforming step has a reverse flowforming component.

37. The method of claim 24, wherein the flowforming step has a forward flowforming component.

38. The method of claim 24, wherein the formed sputtering target tube is 30 feet long or less.

39. The method of claim 24, wherein the formed sputtering target tube has an inner diameter of 15 inches or less

40. The method of claim 24, wherein the formed sputtering target tube has an outer diameter of 15 inches or less.

41. The method of claim 24, wherein the formed sputtering target tube has a wall thickness of at least 0.010 inches.

42. The method of claim 24, wherein the formed sputtering target tube has a dog bone shape.

43. The method of claim 24, wherein the formed sputtering target tube has a wall thickness at one or more positions along the length of the target that is unequal to the wall thickness at the remaining positions along the length of the formed sputtering target tube.

44. The method of claim 24, wherein the formed sputtering target tube includes at least one metal selected from the group consisting of aluminum, cobalt, chromium, copper, indium, iron, magnesium, manganese, molybdenum, nickel, niobium, palladium, platinum, silver, stainless steel, tantalum, tin, titanium, tungsten, vanadium, zinc, zirconium, and alloys thereof.

45. The method of claim 24, wherein the formed sputtering target tube has two open ends.

46. A sputtering target, comprising a hollow cylinder having two open ends and a major axis, wherein at least a portion of the hollow cylinder is made of a metal having an hcp crystal structure having hexagonal crystal cells, the hexagonal cells having basal planes aligned in a radial direction.

47. The sputtering target of claim 46, wherein the metal has an average grain diameter in a radial orientation is no greater than about 0.00025 inches.

48. The sputtering target of claim 47, wherein the average grain diameter in the radial orientation is no greater than about 0.0001 inches.

49. The sputtering target of claim 46, wherein the sputtering target is 30 feet long or less.

50. The sputtering target of claim 46, wherein the sputtering target has an inner diameter of 15 inches or less.

51. The sputtering target of claim 46, wherein the sputtering target has an outer diameter of 15 inches or less.

52. The sputtering target of claim 46, wherein the sputtering target has a wall thickness of at least 0.010 inches.

53. The sputtering target of claim 46, wherein the sputtering target has a dog bone shape.

54. The sputtering target of claim 46, wherein the sputtering target includes at least one metal selected from the group consisting of beryllium, cobalt, neodymium, ruthenium, zinc, zirconium, and alloys thereof.

55. The sputtering target of claim 46, wherein the sputtering target is 100% dense.
